(19) United States
(12) Patent Application Publication
(10) Pub. No.: US 2025/0126717 A1
(43) Pub. Date: Apr. 17, 2025

(54) CIRCUIT BOARD AND ELECTRONIC COMPONENT PACKAGE

(71) Applicant: SAMSUNG ELECTRO-MECHANICS CO., LTD., Suwon-si (KR)

(72) Inventors: Cheolmin Shin, Suwon-si (KR); Kigon Kim, Suwon-si (KR); Dongho Park, Suwon-si (KR); Kangwon Kim, Suwon-si (KR)

(73) Assignee: SAMSUNG ELECTRO-MECHANICS CO., LTD., Suwon-si (KR)

(21) Appl. No.: 18/653,368

(22) Filed: May 2, 2024

(30) Foreign Application Priority Data
Oct. 11, 2023 (KR) 10-2023-0135380
Jan. 19, 2024 (KR) 10-2024-0008816

(51) Int. Cl. H05K 1/18; H05K 1/11

(52) U.S. Cl. CPC H05K 1/183; H05K 1/111; H05K 2201/09427; H05K 2201/09472; H05K 2201/099; H05K 2201/10015; H05K 2201/1003; H05K 2201/10522; H05K 2201/10651

(57) ABSTRACT

An embodiment of the present disclosure provides a circuit board including: an insulating layer including a first area on one surface on which an electronic component is mounted and a second area adjacent to the first area; a connection pad disposed in the first area; and a solder resist layer covering the one surface of the insulating layer and being opened to expose the connection pad. At least a portion of the solder resist layer extends from the second area to the first area, and a portion of the insulating layer is exposed from the solder resist layer in the first area.

### CROSS-REFERENCE TO RELATED APPLICATION

This application claims priority to and the benefit of Korean Patent Application No. 10-2024-0008816 filed in the Korean Intellectual Property Office on Jan. 19, 2024, and Korean Patent Application No. 10-2023-0135380 filed in the Korean Intellectual Property Office on Oct. 11, 2023, the entire contents of which are incorporated herein by reference.

### TECHNICAL FIELD

The present disclosure relates to a circuit board and an electronic component package.

### BACKGROUND

Surface mount technology is a technology that mounts electronic components such as capacitors and inductors on a surface of a package substrate, and has advantages in improving electrical performance of an electronic component packages and in down-sizing it. Recently, in order to improve packaging performance, the demand for surface mounting of passive components with a three-terminal structure developed from the existing two-terminal structure, is increasing.

Since surface-mounted electronic components are vulnerable to physical and chemical impacts from the outside, physical and electrical reliability must be secured through a molding process that fills an empty space using a filler such as an epoxy resin.

In the case of a mold void phenomenon, which is a major defect that may occur during the molding process, it may be fatal to packaging reliability because it is difficult to determine whether it is defective by appearance. Due to changes in the structure of the passive component, a filling problem of the mold may occur under the surface mount component, so improvement is necessary.

### SUMMARY

An aspect of the present disclosure is to provide a circuit board and an electronic component package that may secure a sufficient separation distance between a circuit board and a mounted component on a surface of the circuit board, improve cleaning power under a mounted electronic component during a surface mounting process, and prevent defects caused by flux residues.

However, the objective of the present disclosure is not limited to the aforementioned one, and may be extended in various ways within the spirit and scope of the present disclosure.

An embodiment provides a circuit board including: an insulating layer including a first area on one surface on which an electronic component is mounted and a second area adjacent to the first area; a connection pad disposed in the first area; and a solder resist layer covering the one surface of the insulating layer and being opened to expose the connection pad. At least a portion of the solder resist layer extends from the second area to the first area, and a portion of the insulating layer is exposed from the solder resist layer in the first area.

The solder resist layer may include a first portion disposed in the first area and a second portion disposed in the second area, and the first portion may be disposed adjacent to one edge of the connection pad.

The solder resist layer may include a first portion disposed in the first area and a second portion disposed in the second area, and the first portion may be disposed to at least partially overlap the connection pad in a first direction perpendicular to the one surface of the insulating layer.

The solder resist layer may include a first opening opened to expose at least a portion of the connection pad and a second opening opened to expose a portion of the insulating layer in the first area, and the first opening and the second opening may be integrally connected.

The solder resist layer may include a first portion disposed in the first area and a second portion disposed in the second area, a first opening opened to expose at least a portion of the connection pad, and a second opening opened to expose a portion of the insulating layer in the first area, and the first opening and the second opening may be separated from each other by the first portion.

The first portion may extend along one edge of the second opening.

Another embodiment provides a circuit board including: an insulating layer including a first area on one surface on which an electronic component is mounted and a second area adjacent to the first area; a connection pad disposed in the first area; and a solder resist layer covering the one surface of the insulating layer and being opened to expose the connection pad. A thickness, along a first direction perpendicular to the one surface of the insulating layer, of a first portion of the solder resist layer covering the first area is thicker than a thickness, along the first direction perpendicular to the one surface of the insulating layer, of a second portion of the solder resist layer covering the second area.

The electronic component may include a body and an electrode portion disposed on the body and connected to the connection pad, and at least a portion of the first portion may be disposed to overlap the connection pad along the first direction.

The solder resist layer may include an opening opened to expose a portion of the insulating layer in the first area, a plurality of the connection pads may be provided to be spaced apart from each other with the opening therebetween, and the first portion may be disposed between the plurality of the connection pads. The first portion may be disposed to overlap one corner portion of the first area along the first direction.

The first portion may be disposed to be spaced apart from the connection pad in the first area.

The solder resist layer may include a first opening opened to expose at least a portion of the connection pad and a second opening opened to expose a portion of the insulating layer in the first area.

The first opening and the second opening may be integrally connected.

The first opening and the second opening may be separated from each other by the first portion.

A plurality of second openings may be provided, and the first portion may be disposed between the plurality of second openings.

The first portion may extend along one edge of the second opening.

The solder resist layer may include a first solder resist layer disposed on the one surface of the insulating layer, and a second solder resist layer disposed on the first solder resist layer to protrude from the first solder resist layer in the first direction.

In a planar area in a plane parallel to the one surface of the insulating layer, a planar area of the second solder resist layer may be smaller than that of the first solder resist layer.

Another embodiment provides an electronic component package including: an insulating layer including a first area and a second area; an electronic component mounted in the first area, a connection pad disposed in the first area; and a solder resist layer that covers the one surface of the insulating layer, is opened to expose the connection pad, and is disposed to support the electronic component.

The solder resist layer may include a first portion that is disposed to overlap the electronic component in a first direction perpendicular to the one surface of the insulating layer to support the electronic component.

A height of a lower surface of the electronic component from the one surface of the insulating layer along the first direction may be equal to a height of an upper surface of the first portion from the one surface of the insulating layer along the first direction or may be higher than the height of the upper surface of the first portion from the one surface of the insulating layer along the first direction.

The first portion may include a portion that is in direct contact with the electronic component.

The electronic component package may further include a connection portion arranged to connect the electronic component and the connection pad to each other, wherein at least a portion of the connection portion may be disposed between the electronic component and the solder resist layer along a first direction perpendicular to the one surface of the insulating layer.

The connection pad may be embedded in the insulating layer and one surface thereof may be exposed from the insulating layer.

The solder resist layer may include a first opening opened to expose at least a portion of the connection pad, and a second opening opened to expose a portion of the insulating layer in the first area.

The first opening and the second opening may be integrally connected.

The first opening and the second opening may be separated from each other by the first portion.

A plurality of second openings may be provided, and the first portion may be disposed between the plurality of second openings.

The electronic component may include a body and an electrode portion disposed on the body and connected to the connection pad, and the solder resist layer may include a first solder resist layer disposed on the one surface of the insulating layer, and a second solder resist layer disposed on the first solder resist layer to protrude from the first solder resist layer in a first direction perpendicular to the one surface of the insulating layer.

The second solder resist layer may be disposed at both end portions facing each other of the electrode portion.

A plurality of electrode portions may be provided so as to be disposed to face each other in a second direction perpendicular to the first direction, and the second solder resist layer may be disposed at an inner end portion of the electrode portion in the second direction.

A plurality of electrode portions may be provided so as to be disposed to face each other in a second direction perpendicular to the first direction, and the second solder resist layer may be disposed between the plurality of electrode portions.

The second solder resist layer may be disposed between the body of the electronic component and the first solder resist layer in the first direction.

Another embodiment provides an electronic component package including: an insulating layer; a connection pad at least partially embedded in the insulating layer and having one surface exposed from the insulating layer; a solder resist layer disposed on the insulating layer; and a first electronic component disposed on the insulating layer and connected to the connection pad through a connection portion disposed between the connection pad and the first electronic component. A portion of the solder resist layer overlapping the first electronic component in a first direction perpendicular to the one surface includes one opening to expose a portion of the insulating layer.

The connection portion may be disposed in the one opening of the solder resist layer.

The connection portion may be disposed in another opening of the solder resist layer spaced apart from the one opening of the solder resist layer.

A thickness of the portion of the solder resist layer overlapping the first electronic component in the first direction may be greater than a thickness of another portion of the solder resist layer disposed on a region outside the first electronic component viewed in the first direction.

The solder resist layer may include one portion disposed on one side of the connection portion having a thickness greater than another portion disposed on another side of the connection portion.

The solder resist layer may include another opening exposing a plurality of other pads partially embedded in the insulating layer. The circuit board may further comprise a second electronic component disposed on the insulating layer and connected to the plurality of other connection pads through other connection portions disposed in the another opening of the solder resist layer.

A portion of the solder resist layer extending in a region between the first electronic component and the second electronic component may have a thickness less than the portion of the solder resist layer overlapping the first electronic component in the first direction.

Another embodiment provides an electronic component package including: an insulating layer; a connection pad at least partially embedded in the insulating layer and having one surface exposed from the insulating layer; a solder resist layer disposed on the insulating layer; and a first electronic component disposed on the insulating layer and connected to the connection pad through a connection portion disposed between the connection pad and the first electronic component. The solder resist layer includes one opening to expose a portion of the insulating layer which overlaps the first electronic component in a first direction perpendicular to the one surface. In the first direction perpendicular to the one surface, a lower surface of the first electronic component is at a level the same as or above an upper surface of the solder resist layer.

The connection portion may be in contact with the solder resist layer.

According to the circuit board and the electronic component package according to the embodiment, it is possible to secure a sufficient separation distance between a circuit board and a mounted component on a surface of the circuit board, improve cleaning power under a mounted electronic component during a surface mounting process, and prevent defects caused by flux residues.

In addition, according to the circuit board and the electronic component package according to the embodiment, it is possible to prevent mold void defects under a surface-mounted component during a molding process, and to suppress physical and electrical interference effects between the surface-mounted component and the circuit board.

### BRIEF DESCRIPTION OF THE DRAWINGS

FIG. 1 illustrates a schematic cross-sectional view of an electronic component package according to an embodiment.

FIG. 2 illustrates a schematic top plan view of a circuit board according to an embodiment.

FIG. 3 illustrates a cross-sectional view of a portion of an electronic component package according to an embodiment.

FIG. 4 illustrates a cross-sectional view of a portion of an electronic component package according to a modified example.

FIG. 5 illustrates a schematic top plan view of a circuit board according to another embodiment.

FIG. 6 illustrates a cross-sectional view of a portion of an electronic component package according to another embodiment.

FIG. 7 illustrates a schematic cross-sectional view of an electronic component package according to another embodiment.

FIG. 8 illustrates a schematic top plan view of a circuit board according to another embodiment.

FIG. 9 illustrates a cross-sectional view of a portion of an electronic component package according to another embodiment.

FIG. 10 illustrates a schematic cross-sectional view of an electronic component package according to another embodiment.

FIG. 11 illustrates a schematic top plan view of a circuit board according to another embodiment.

FIG. 12 illustrates a cross-sectional view of a portion of an electronic component package according to another embodiment.

FIG. 13 illustrates a schematic cross-sectional view of an electronic component package according to another embodiment.

FIG. 14 illustrates a schematic top plan view of a circuit board according to another embodiment.

FIG. 15 illustrates a cross-sectional view of a portion of an electronic component package according to another embodiment.

### DETAILED DESCRIPTION OF THE EMBODIMENTS

The present disclosure will be described more fully hereinafter with reference to the accompanying drawings, in which embodiments of the disclosure are shown. The drawings and description are to be regarded as illustrative in nature and not restrictive. Like reference numerals designate like elements throughout the specification. In addition, some constituent elements are exaggerated, omitted, or briefly illustrated in the added drawings, and sizes of the respective constituent elements do not reflect the actual sizes.

The accompanying drawings are provided only in order to allow embodiments disclosed in the present specification to be easily understood and are not to be interpreted as limiting the spirit disclosed in the present specification, and it is to be understood that the present disclosure includes all modifications, equivalents, and substitutions without departing from the scope and spirit of the present disclosure.

Terms including an ordinal number, such as first, second, etc., may be used to describe various elements, but the elements are not limited by the terms. These terms are only used to differentiate one constituent element from another.

It will be understood that when an element such as a layer, film, region, area, or substrate is referred to as being “on” or “above” another element, it can be directly on the other element or intervening elements may also be present. In contrast, when an element is referred to as being “directly on” another element, there are no intervening elements present. Further, in the specification, the word “on” or “above” means disposed on or below the object portion, and does not necessarily mean disposed on the upper side of the object portion based on a gravitational direction.

Throughout the specification, it should be understood that the term “include”, “comprise”, “have”, or “configure” indicates that a feature, a number, a step, an operation, a constituent element, a part, or a combination thereof described in the specification is present, but does not exclude a possibility of presence or addition of one or more other features, numbers, steps, operations, constituent elements, parts, or combinations, in advance. Unless explicitly described to the contrary, the word “comprise” and variations such as “comprises” or “comprising” will be understood to imply the inclusion of stated elements but not the exclusion of any other elements.

Further, throughout the specification, the phrase “in a plan view” or “on a plane” means viewing a target portion from the top, and the phrase “in a cross-sectional view” or “on a cross-section” means viewing a cross-section formed by vertically cutting a target portion from the side.

Throughout this specification and the claims that follow, when it is described that an element is “coupled” to another element, the element may be “directly or physically coupled” to the other element or “indirectly coupled or non-contact coupled” to the other element through a third element.

Furthermore, throughout the specification, “connected” does not only mean when two or more elements are directly connected, but also when two or more elements are indirectly connected through other elements, and when they are physically connected or electrically connected, and further, it may be referred to by different names depending on a position or function, and may also be referred to as a case in which respective parts that are substantially integrated are linked to each other.

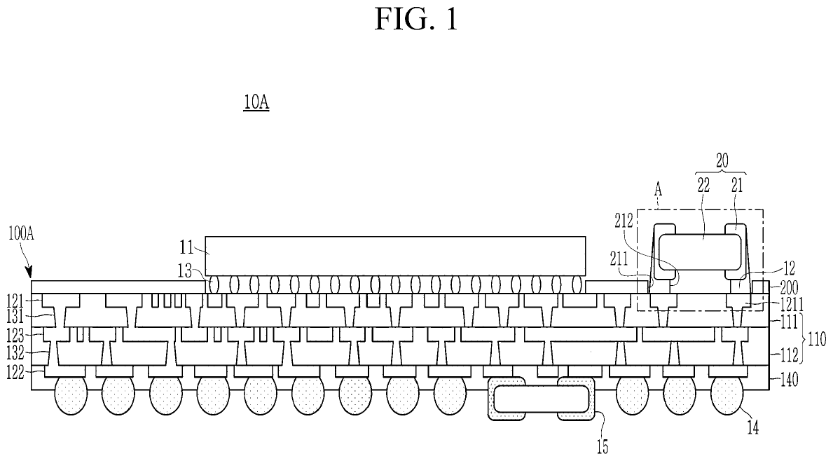

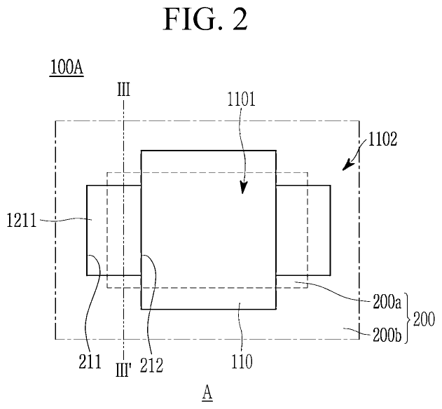

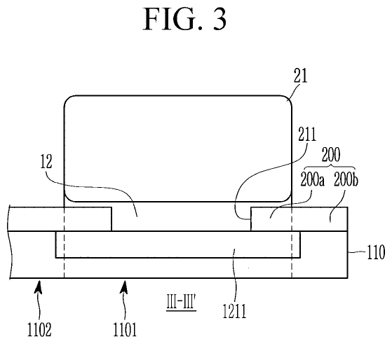

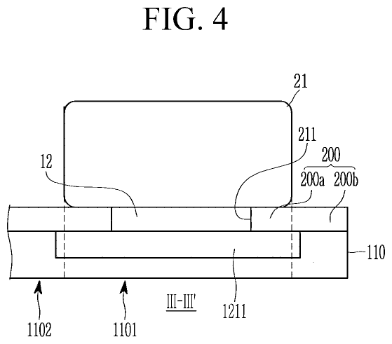

FIG. 1 illustrates a schematic cross-sectional view of an electronic component package according to an embodiment, FIG. 2 illustrates a schematic top plan view of a circuit board according to an embodiment, FIG. 3 illustrates a cross-sectional view of a portion of an electronic component package according to an embodiment, and FIG. 4 illustrates a cross-sectional view of a portion of an electronic component package according to a modified example.

FIG. 2 illustrates a top plan view of portion “A” of FIG. 1, excluding electronic components. FIG. 3 illustrates a cross-sectional view of a state in which an electronic component is disposed on a circuit board according to an embodiment taken along line III-III′ of FIG. 2. FIG. 4 illustrates a cross-sectional view of a state in which an electronic component is disposed on a circuit board according to a modified example embodiment taken along line III-III′ of FIG. 2.

Referring to FIG. 1, an electronic component package 10A according to an embodiment may include a circuit board 100A, a first electronic component 20 and a second electronic component 11 mounted on one surface of the circuit board 100A. The electronic component package 10A according to the embodiment may include a first connection portion 12 connecting the first electronic component 20 and the circuit board 100A, a second connection portion 13 connecting the second electronic component 11 and the circuit board 100A, and a third connection portion 14 connecting the circuit board 100A to the outside. In addition, the electronic component package 10A according to the embodiment may include a third electronic component 15 mounted on the other surface of the circuit board 100A.

The first electron component 20 may be mounted on one surface of an insulating layer 110 of the circuit board 100A. The first electronic component 20 may include a chip-type passive component, for example, a chip-type inductor or a chip-type capacitor, but is not limited thereto.

The first electronic component 20 may include a body 22 and an electrode portion 21 disposed on the body 22 and electrically connected to the circuit board 100A. In FIG. 1, the electrode portion 21 is shown as being disposed on both sides of the body 22, but is not limited thereto, and the electrode portion 21 may be disposed singly on the body 22, or three or more electrode portion 21 may be disposed thereon. The body 22 may include a dielectric material. The body 22 may include a plurality of surfaces facing each other. The electrode portion 21 of the first electronic component 20 may include a metal material such as copper (Cu) or aluminum (Al). The electrode portion 21 may be electrically connected to the circuit board 100A through the first connection portion 12.

The second electronic component 11 may be an integrated circuit (IC) die in which hundreds to millions of components are integrated into one chip. For example, the second electronic component 11 may be a processor chip such as a central processor (for example, CPU), a graphics processor (for example, a GPU), a field programmable gate array (FPGA), a digital signal processor, a cryptographic processor, a microprocessor, a microcontroller, and the like, specifically an application processor (AP), but is not limited thereto, and it may be a memory such as other volatile memory (for example, a DRAM), a non-volatile memory (for example, a ROM), and a flash memory, an analog-to-digital converter, or a logic such as an application-specific IC (ASIC). As necessary, the second electronic component 11 may be a chip-type passive component, for example, a chip-type inductor or a chip-type capacitor. The second electronic component 11 may be electrically connected to the circuit board 100A through the second connection portion 13. The second electronic component 11 may be attached to one surface of the circuit board 100A using an adhesive film or the like, as necessary.

The third electronic component 15 may include a chip-type passive component, for example, a chip-type inductor or a chip-type capacitor, but is not limited thereto, and may be an integrated circuit (IC) die in which hundreds to millions of components are integrated into a single chip. The third electronic component 15 may be electrically connected to the circuit board 100A.

The first connection portion 12 may be disposed inside a first opening 211 of a solder resist layer 200 of the circuit board 100A. The first connection portion 12 may electrically connect an exposed first wiring layer 121 and the first electronic component 20. The first connection portion 12 may electrically connect the exposed first wiring layer 121 and the electrode portion 21 of the first electronic component 20. The first connection portion 12 may physically and/or electrically connect the first electronic component 20 surface-mounted on the circuit board 100A to the circuit board 100A. The first connection portion 12 may be made of tin (Sn) or an alloy containing tin (Sn), for example, solder and the like, but is not limited thereto. The first connection portion 12 may be disposed between the electrode portion 21 of the first electronic component 20 and the first wiring layer 121. The first connection portion 12 may be disposed between the electrode portion 21 of the first electronic component 20 and a connection pad 1211. The electrode portion 21 may be electrically connected to the connection pad 1211. At least a portion of the first connection portion 12 may be disposed between the first electronic component 20 and the solder resist layer 200 in a first direction perpendicular to one surface of the insulating layer 110.

The second connection portion 13 may be disposed inside another opening of the solder resist layer 200 of the circuit board 100A. The second connection portion 13 may electrically connect the exposed first wiring layer 121 and the second electronic component 11. The second connection portion 13 may physically and/or electrically connect the second electronic component 11 surface-mounted on the circuit board 100A to the circuit board 100A. The second connection portion 13 may be made of tin (Sn) or an alloy containing tin (Sn), for example, solder and the like, but is not limited thereto. For example, the second connection portion 13 may have a ball shape, but is not limited thereto, and may have a shape such as a land, a pin, or a column-shaped metal post.

Each of a plurality of third connection portions 14 may be electrically connected to an exposed third wiring layer 123. The third connection portion 14 may physically and/or electrically connect the circuit board 100A to the outside. For example, the circuit board 100A may be mounted on a main board of an electronic component or another BGA substrate through this. Each of the plurality of third connections 14 may be made of tin (Sn) or an alloy containing tin (Sn), for example, solder and the like, but is not limited thereto. For example, the third connection portion 14 may have a ball shape, but is not limited thereto, and may have a shape such as a land, a pin, or a column-shaped metal post.

Hereinafter, the circuit board 100A according to the embodiment will be described in more detail.

Referring to FIG. 1, the circuit board 100A according to the embodiment may include the insulating layer 110, the first and second wiring layers 121 and 122 disposed on one surface and the other surface of the insulating layer 110, and the third wiring layer 123 disposed between the first wiring layer 121 and the second wiring layer 122 and embedded in the insulating layer 110. In addition, the circuit board 100A according to the embodiment may include a first via layer 131 that penetrates at least a portion of the insulating layer 110 and is connected to the first wiring layer 121, and a second via layer 132 that penetrates at least a portion of the insulating layer 110 and is connected to the second wiring layer 122.

The insulating layer 110 may include a plurality of insulating layers 111 and 112. For example, the insulating layer 110 may include first and second insulating layers 111 and 112.

As a material of the plurality of insulating layers 111 and 112, an insulating material may be used, and as the insulating material, a thermosetting resin such as an epoxy resin or a thermoplastic resin such as polyimide may be used. In addition, these resins including inorganic fillers such as silica and reinforcing materials such as glass fiber may be used. For example, prepreg and Ajinomoto build-up film (ABF) may be used, but the present disclosure is not limited thereto. Meanwhile, the ABF may be provided in the form of resin coated copper (RCC), but is not limited thereto. As necessary, a photosensitive material such as a photo image-able dielectric (PIE) may be used.

Referring to FIG. 1, the insulating layer 110 is shown as being configured of two layers including the first and second insulating layers 111 and 112, but the insulating layer 110 may also be configured of a single layer, and may include a larger number of layers.

The circuit board 100A according to the present embodiment may include a plurality of wiring layers 121, 122, and 123. The plurality of wiring layers 121, 122, and 123 may include the first to third wiring layers 121, 122, and 123. Each of the first to third wiring layers 121, 122, and 123 may be disposed on at least one of the inside and the outside of the insulating layer 110.

The wiring layers 121, 122, and 123 may transmit signals inside the circuit board 100A. A metal material may be used as a material for the wiring layers 121, 122, and 123. The metal material may include copper (Cu), aluminum (Al), silver (Ag), tin (Sn), gold (Au), nickel (Ni), lead (Pb), titanium (Ti), or an alloy thereof. The wiring layers 121, 122, and 123 may perform various functions depending on a design such as a ground pattern, a power pattern, and a signal pattern. These patterns may each have a line, plane, or pad shape. The wiring layer disposed on the outermost layer among the plurality of wiring layers 121, 122, and 123 may function as a pad for connection to other boards or components.

Each of the plurality of wiring layers 121, 122, and 123 may be formed by a plating process such as an additive process (AP), a semi AP (SAP), a modified SAP (MSAP), and a tenting (TT).

The first wiring layer 121 may be disposed on the first insulating layer 111. For example, the circuit board 100A according to an embodiment may be manufactured using an embedded trace substrate (ETS) method. The insulating layer 110 may have one surface and the other surface facing each other, and in this case, the first wiring layer 121 may be embedded and disposed on one surface side of the insulating layer 110. That is, the first wiring layer 121 may be embedded from one surface of the insulating layer 110.

The first wiring layer 121 may include a portion embedded in one surface of the insulating layer 110 so that an upper surface thereof is exposed. The first wiring layer 121 may include the connection pad 1211 embedded in one surface of the insulating layer 110 so that an upper surface thereof is exposed. The connection pad 1211 may be embedded in the insulating layer 110, so that one surface thereof may be exposed from the insulating layer 110. The first wiring layer 121 may include a plurality of connection pad 1211.

The second wiring layer 122 may be disposed on the other surface of the insulating layer 110. The second wiring layer 122 may be disposed to protrude from the other surface of the insulating layer 110. The second wiring layer 122 may be disposed on the second insulating layer 112. The second wiring layer 122 may function as a pad for connection to other boards or components.

The third wiring layer 123 may be disposed on one surface of the first insulating layer 111. The third wiring layer 123 may be embedded in the second insulating layer 112. Referring to FIG. 1, the third wiring layer 123 is shown as being disposed between the first wiring layer 121 and the second wiring layer 122, but this is an example, and the third wiring layer 123 may not be disposed, or a plurality of wiring layers may exist.

Referring to FIG. 1, the first to third wiring layers 121, 122, and 123 are illustrated, but the present disclosure is not limited thereto, and a larger number of wiring layers may be disposed, or a smaller number of wiring layers may be disposed.

The circuit board 100A according to the embodiment may include the first via layer 131 penetrating the first insulating layer 111 and electrically connecting the first and third wiring layers 121 and 123, and the second via layer 132 penetrating the second insulating layer 112 and electrically connecting the second and third wiring layers 122 and 123. Each via layer may include a plurality of vias filled with conductors within a plurality of via holes.

A metal material may be used as a material of the plurality of via layers 131 and 132, and as the metal material, copper (Cu), aluminum (Al), silver (Ag), tin (Sp), gold (Au), nickel (Ni), lead (Pb), titanium (Ti), or an alloy thereof may be used. The plurality of via layers 131 and 132 may include a signal via, a ground via, a power via, or the like depending on a design. Each of the vias of the plurality of via layers 131 and 132 may be completely filled with a metal material, or may be partially filled due to a metal material being formed along the wall of the via hole. The plurality of via layers 131 and 132 may also be formed by a plating process, for example, a process such as an AP, an SAP, an MSAP, a TT, or the like, and may include a seed layer that is an electroless plating layer and an electrolytic plating layer formed based on the seed layer. The vias of each of the first and second via layers 131 and 132 may have a tapered shape in which a width of one surface is smaller than a width of the other surface.

Meanwhile, in FIG. 1, the plurality of via layers are shown as having two layers of the first and second via layers 131 and 132, but depending on the configuration of the insulating layer 110 and the design of the wiring layer, the via layer may be configured as a single layer or may have more layers.

The circuit board 100A according to the embodiment may include the solder resist layer 200. The solder resist layer 200 may protect internal components from external physical and chemical damage.

The solder resist layer 200 may have at least one first opening 211. The solder resist layer 200 may cover one surface of the insulating layer 110, and may be opened to expose at least a portion of the connection pad 1211. At least one first opening 211 of the solder resist layer 200 may expose at least a portion of the first wiring layer 121, respectively. At least a portion of the connection pad 1211 may be exposed from the solder resist layer 200 through the first opening 211 of the solder resist layer 200. The solder resist layer 200 may include a photosensitive resin material.

The circuit board 100A according to the embodiment may include a passivation layer 140. The passivation layer 140 may protect internal components from external physical and chemical damage. The passivation layer 140 may be a solder resist layer. The passivation layer 140 may have at least one opening. The passivation layer 140 may cover the other surface of the insulating layer 110, and may be opened to expose the second wiring layer 122. At least one opening of the passivation layer 140 may expose at least a portion of the second wiring layer 122, respectively. The passivation layer 140 may include a photosensitive resin material.

Hereinafter, the solder resist layer 200 of the circuit board 100A according to the embodiment will be described in more detail with reference to FIG. 1 to FIG. 3.

Referring to FIG. 2 and FIG. 3, the insulating layer 110 may include a first area 1101 and a second area 1102. The first area 1101 may be provided so that the first electronic component 20 is mounted. The second area 1102 may be an area adjacent to the first area 1101.

For example, the first area 1101 may mean an area on one surface of the insulating layer 110 in which the insulating layer 110 and the first electronic component 20 overlap in a first direction perpendicular to one surface of the insulating layer 110. The first electronic component 20 may be mounted in the first area 1101. The second area 1102 may mean an area in which the first electronic component 20 is not mounted. The second area 1102 may be connected to the first area 1101. The second area 1102 may include a portion surrounding the first area 1101.

The connection pad 1211 may be disposed in the first area 1101. At least a portion of the connection pad 1211 may be exposed from the insulating layer 110 in the first area 1101.

At least one connection pad 1211 may be disposed on the first area 1101 of the insulating layer 110. The connection pad 1211 may be disposed at a position corresponding to a portion in which the electrode portion 21 of the first electronic component 20 overlaps the first area 1101. For example, when the electrode portions 21 are disposed on both sides of the first area 1101, the connection pads 1211 may be disposed on both sides of the first area 1101.

Among the first area 1101, there may be a portion in which neither the connection pad 1211 nor the solder resist layer 200 is disposed on the insulating layer 110. Accordingly, a portion of one surface of the insulating layer 110 in the first area 1101 may be exposed from the solder resist layer 200.

A portion of the solder resist layer 200 may be disposed on the second area 1102. At least a portion of the solder resist layer 200 may extend from the second area 1102 to the first area 1101. In other words, the solder resist layer 200 may include a first portion 200a disposed in the first area 1101 and a second portion 200b disposed in the second area 1102. The first portion 200a may cover a portion of the first area 1101. The second portion 200b may cover at least a portion of the second area 1102.

The first portion 200a of the solder resist layer 200 may be disposed on the first area 1101. The first portion 200a may overlap the first electronic component 20 along the first direction. The first portion 200a may be disposed to overlap a corner portion of the first electronic component 20. The first portion 200a may be disposed to at least partially overlap the connection pad 1211 along the first direction. The first portion 200a may be disposed on the connection pad 1211.

The solder resist layer 200 may be disposed to support the first electronic component 20. The first portion 200a may be disposed to support the first electronic component 20. Along the first direction, the first connection portion 12 may be disposed between the first portion 200a and the first electronic component 20. Along the first direction, there may be a portion in which the first electronic component 20, the first connection portion 12, and the first portion 200a are sequentially disposed. Referring to FIG. 3, in a height from one surface of the insulating layer 110 in the first direction, a height of the lower surface of the first electronic component 20 may be higher than a height of the upper surface of the first portion 200a. The first portion 200a may be in contact with the first connection portion 12.

Referring to FIG. 4, the first portion 200a of the circuit board 100A according to a modified example may include a portion that is in direct contact with the first electronic component 20. In the height from one surface of the insulating layer 110 in the first direction, the height of the lower surface of the first electronic component 20 may be the same as the height of the upper surface of the first portion 200a. The first portion 200a may be in contact with the first connection portion 12.

The first portion 200a may be disposed adjacent to one edge of the connection pad 1211. The first portion 200a can be disposed along one edge of the connection pad 1211. The first portion 200a may extend along one edge of the connection pad 1211 disposed in the first area 1101. The first portion 200a may be disposed between the first electronic component 20 and the connection pad 1211 along the first direction. The first portion 200a may be disposed between the electrode portion 21 of the first electronic component 20 and the connection pad 1211 along the first direction.

A second direction may be perpendicular to the first direction and parallel to a direction in which a plurality of electrode portions 21 of the first electronic component 20 face each other. A third direction may be a direction perpendicular to the first and second directions. The first portion 200a may have a shape in which a portion of the second portion 200b extends in the third direction. The first portion 200a may have a shape in which a portion of the second portion 200b disposed in an edge area of the connection pad 1211 along the third direction extends in the third direction. The first portion 200a may extend from the second portion 200b toward the inside of the electrode portion 21 of the first electronic component 20. The first portion 200a may be disposed adjacent to an outer end portion of the electrode portion 21 in the second direction.

The solder resist layer 200 may have a second opening 212 exposing the insulating layer 110 from the solder resist layer 200. The second opening 212 may be opened to expose a portion of one surface of the insulating layer 110 in the first area 1101. The second opening 212 may be surrounded by the solder resist layer 200 and one side of the connection pad 1211. The second opening 212 may be integrally connected to the first opening 211.

A plurality of first portions 200a may be provided in the first area 1101. The plurality of first portions 200a may be disposed to face each other in the third direction. The plurality of first portions 200a may be disposed adjacent to both end portions of the electrode portion 21 in the third direction.

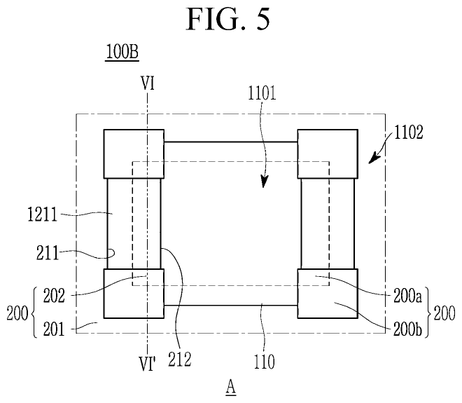

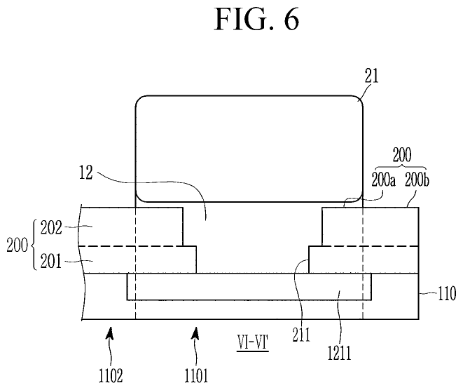

Hereinafter, a solder resist layer 200 of a circuit board 100B according to another embodiment will be described with reference to FIG. 5 and FIG. 6 together with FIG. 1.

FIG. 5 illustrates a schematic top plan view of a circuit board according to another embodiment, and FIG. 6 illustrates a cross-sectional view of a portion of an electronic component package according to another embodiment.

FIG. 5 illustrates a top plan view of portion “A” of FIG. 1, excluding electronic components. FIG. 6 illustrates a cross-sectional view of a state in which an electronic component is disposed on a circuit board according to another embodiment taken along line VI-VI′ of FIG. 5.

Referring to FIG. 5 and FIG. 6, in the circuit board 100B according to another embodiment, compared to the circuit board 100A according to the embodiment of the present disclosure, the solder resist layer 200 may include first and second solder resist layers 201 and 202. Therefore, in describing the structure of the circuit board 100B according to another embodiment, only the changed configuration compared to the configuration of the circuit board 100A according to the embodiment will be described. The description of the electronic component package 10A according to the above-described embodiment may be applied to the remaining configuration of the electronic component package 10A.

A portion of the solder resist layer 200 may be disposed on the second area 1102. At least a portion of the solder resist layer 200 may extend from the second area 1102 to the first area 1101. In other words, the solder resist layer 200 may include the first portion 200a disposed in the first area 1101 and the second portion 200b disposed in the second area 1102.

The first portion 200a of the solder resist layer 200 may be disposed on the first area 1101. The first portion 200a may overlap the first electronic component 20 along the first direction. The first portion 200a may be disposed to overlap a corner portion of the first electronic component 20. The first portion 200a may be disposed to at least partially overlap the connection pad 1211 along the first direction. The first portion 200a may be disposed on the connection pad 1211.

The solder resist layer 200 may be disposed to support the first electronic component 20. The first portion 200a may be disposed to support the first electronic component 20. Along the first direction, the first connection portion 12 may be disposed between the first portion 200a and the first electronic component 20. Along the first direction, there may be a portion in which the first electronic component 20, the first connection portion 12, and the first portion 200a are sequentially disposed. In the height from one surface of the insulating layer 110 in the first direction, the height of the lower surface of the first electronic component 20 may be higher than the height of the upper surface of the first portion 200a. The first portion 200a may be in contact with the first connection portion 12.

The first portion 200a may include a portion that is in direct contact with the first electronic component 20. In the height from one surface of the insulating layer 110 in the first direction, the height of the lower surface of the first electronic component 20 may be the same as the height of the upper surface of the first portion 200a. The first portion 200a may be in contact with the first connection portion 12.

The first portion 200a may be disposed adjacent to one edge of the connection pad 1211. The first portion 200a can be disposed along one edge of the connection pad 1211. The first portion 200a may extend along one edge of the connection pad 1211 disposed in the first area 1101. The first portion 200a may be disposed between the first electronic component 20 and the connection pad 1211 along the first direction. The first portion 200a may be disposed between the electrode portion 21 of the first electronic component 20 and the connection pad 1211 along the first direction.

A second direction may be perpendicular to the first direction and parallel to a direction in which the electrode portion 21 of the first electronic component 20 faces. A third direction may be a direction perpendicular to the first and second directions. The first portion 200a may have a shape in which a portion of the second portion 200b extends in the third direction. The first portion 200a may have a shape in which a portion of the second portion 200b disposed in an edge area of the connection pad 1211 along the third direction extends in the third direction. The first portion 200a may extend from the second portion 200b toward the inside of the electrode portion 21 of the first electronic component 20. The first portion 200a may be disposed adjacent to an outer end portion of the electrode portion 21 in the second direction.

The solder resist layer 200 may have the second opening 212 exposing the insulating layer 110 from the solder resist layer 200. The second opening 212 may be opened to expose a portion of one surface of the insulating layer 110 in the first area 1101. The second opening 212 may be integrally connected to the first opening 211. In other words, the connection pad 1211 and the insulating layer 110 may be exposed together by one opening including the first opening 211 and the second opening 212.

A plurality of first portions 200a may be provided in the first area 1101. The plurality of first portions 200a may be disposed to face each other in the third direction. The plurality of first portions 200a may be disposed adjacent to both end portions of the electrode portion 21 in the third direction.

Referring to FIG. 5 and FIG. 6, in a thickness along the first direction, a thickness of the first portion 200a of the solder resist layer 200 may be greater than that of the second portion 200b. Specifically, the solder resist layer 200 may include a protrusion having a thickness greater than that of the remaining portion in the first direction in an area adjacent to the first electronic component 20. In other words, the solder resist layer 200 may include a first solder resist layer 201 disposed on the insulating layer 110 and a second solder resist layer 202 disposed on the first solder resist layer 201. The second solder resist layer 202 may include at least one solder resist patch. The first solder resist layer 201 may have an expanded shape to cover one surface of the insulating layer 110. The first solder resist layer 201 may have a first opening 211 that exposes at least a portion of the connection pad 1211.

The second solder resist layer 202 may be disposed to protrude from the first solder resist layer 201 in the first direction. The second solder resist layer may be disposed between the first electronic component 20 and the first solder resist layer 201 along the first direction. The second solder resist layer 202 may be disposed to face the third direction. The second solder resist layer 202 may be disposed at opposite end portions of the electrode portion 21 in the third direction, respectively. Along the first direction, the first connection portion 12 may be disposed between the first electronic component 20 and the second solder resist layer 202. Along the first direction, there may be a portion in which the first electronic component 20, the first connection portion 12, the second solder resist layer 202, and the first solder resist layer 201 are sequentially disposed.

In a planar area in a plane parallel to one surface of the insulating layer 110, a planar area of the second solder resist layer 202 may be smaller than that of the first solder resist layer 201. The second solder resist layer 202 may be made of the same material as the first solder resist layer 201, but is not limited thereto, and may be made of a different material.

The first portion 200a may include portions of the first and second solder resist layers 201 and 202. The second portion 200b may include other portions of the first and second solder resist layers 201 and 202.

At least a portion of the first portion 200a may be disposed to support the first electronic component 20. At least a portion of the first portion 200a may be disposed to overlap the first electronic component 20 in the first direction. At least a portion of the first portion 200a may be disposed to overlap the electrode portion 21 in the first direction. At least a portion of the first portion 200a may be disposed to at least partially overlap the connection pad 1211 in the first direction.

The first portion 200a may be disposed to overlap one corner portion of the first electronic component 20 in the first direction. In other words, the first portion 200a may be disposed to overlap one corner portion of the first area 1101 in the first direction.

A stepped portion in the first direction may be disposed at one edge of the first portion 200a in the third direction. However, it is not limited thereto, and the first solder resist layer 201 and the second solder resist layer 202 configuring the first portion 200a may be disposed to have the same width in the third direction.

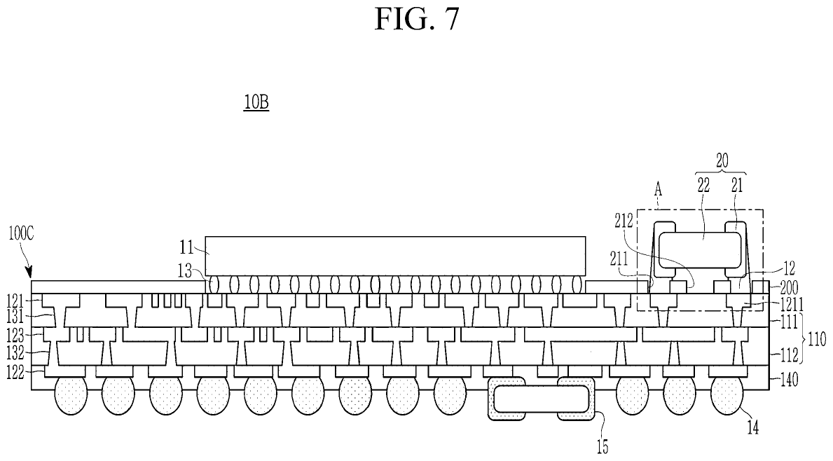

Hereinafter, an electronic component package 10B and a circuit board 100C according to another embodiment will be described with reference to FIG. 7 to FIG. 9.

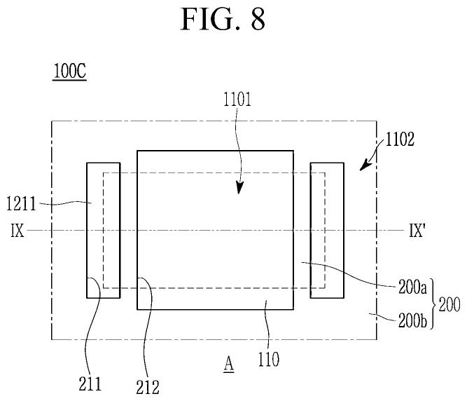

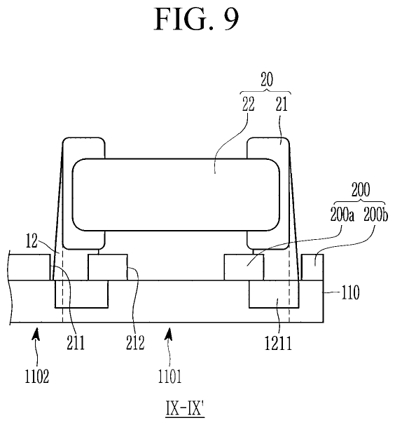

FIG. 7 illustrates a schematic cross-sectional view of an electronic component package according to another embodiment, FIG. 8 illustrates a schematic top plan view of a circuit board according to another embodiment, and FIG. 9 illustrates a cross-sectional view of a portion of an electronic component package according to another embodiment.

FIG. 8 illustrates a top plan view of portion “A” of FIG. 7, excluding electronic components. FIG. 9 illustrates a cross-sectional view of a state in which an electronic component is disposed on a circuit board according to another embodiment taken along line IX-IX′ of FIG. 8.

Referring to FIG. 7 to FIG. 9, the circuit board 100C according to another embodiment may have a different disposition or shape of the solder resist layer 200 compared to the circuit board 100A according to the embodiment described with reference to FIG. 1 to FIG. 3. Therefore, in describing the structure of the circuit board 100C according to another embodiment, only the changed configuration compared to the configuration of the circuit board 100A according to the embodiment will be described. The description of the electronic component package 10B according to the above-described embodiment may be applied to the remaining configuration of the electronic component package 10A.

Referring to FIG. 7 to FIG. 9, the insulating layer 110 may include a first area 1101 and a second area 1102. The insulating layer 110 may include the first area 1101 on which the first electronic component 20 is mounted, and the second area 1102 adjacent to the first area 1101.

For example, the first area 1101 may mean an area on one surface of the insulating layer 110 in which the insulating layer 110 and the first electronic component 20 overlap in a first direction perpendicular to one surface of the insulating layer 110. The first electronic component 20 may be mounted in the first area 1101. The second area 1102 may mean an area in which the first electronic component 20 is not mounted. The second area 1102 may be connected to the first area 1101. The second area 1102 may include a portion surrounding the first area 1101.

The connection pad 1211 may be disposed in the first area 1101. At least a portion of the connection pad 1211 may be exposed from the insulating layer 110 in the first area 1101.

At least one connection pad 1211 may be disposed on the first area 1101 of the insulating layer 110. The connection pad 1211 may be disposed at a position corresponding to a portion in which the electrode portion 21 of the first electronic component 20 overlaps the first area 1101. For example, when the electrode portions 21 are disposed on both sides of the first area 1101, the connection pads 1211 may be disposed on both sides of the first area 1101.

Among the first area 1101, there may be a portion in which neither the connection pad 1211 nor the solder resist layer 200 is disposed on the insulating layer 110. Accordingly, a portion of one surface of the insulating layer 110 in the first area 1101 may be exposed from the solder resist layer 200.

A portion of the solder resist layer 200 may be disposed on the second area 1102. At least a portion of the solder resist layer 200 may extend from the second area 1102 to the first area 1101. In other words, the solder resist layer 200 may include a first portion 200a disposed in the first area 1101 and a second portion 200b disposed in the second area 1102.

The first portion 200a of the solder resist layer 200 may be disposed on the first area 1101. The first portion 200a may overlap the first electronic component 20 along the first direction. The first portion 200a may be disposed to overlap a corner portion of the first electronic component 20. The first portion 200a may be disposed to at least partially overlap the connection pad 1211 along the first direction. The first portion 200a may be disposed on the connection pad 1211.

The solder resist layer 200 may be disposed to support the first electronic component 20. The first portion 200a may be disposed to support the first electronic component 20. Along the first direction, the first connection portion 12 may be disposed between the first portion 200a and the first electronic component 20. Along the first direction, there may be a portion in which the first electronic component 20, the first connection portion 12, and the first portion 200a are sequentially disposed. In the height from one surface of the insulating layer 110 in the first direction, the height of the lower surface of the first electronic component 20 may be higher than the height of the upper surface of the first portion 200a. The first portion 200a may be in contact with the first connection portion 12.

The first portion 200a may include a portion that is in direct contact with the first electronic component 20. In the height from one surface of the insulating layer 110 in the first direction, the height of the lower surface of the first electronic component 20 may be the same as the height of the upper surface of the first portion 200a. The first portion 200a may be in contact with the first connection portion 12.

The first portion 200a may be disposed adjacent to one edge of the connection pad 1211. The first portion 200a can be disposed along one edge of the connection pad 1211. The first portion 200a may extend along one edge of the connection pad 1211 disposed in the first area 1101. The first portion 200a may be disposed between the first electronic component 20 and the connection pad 1211 along the first direction. The first portion 200a may be disposed between the electrode portion 21 of the first electronic component 20 and the connection pad 1211 along the first direction.

On a plane parallel to one surface of the insulating layer 110, the first portion 200a may be disposed between the connection pad 1211 and the insulating layer 110 in the second direction. On a plane parallel to one surface of the insulating layer 110, the connection pad 1211 and the insulating layer 110 may be disposed along the second direction with respect to the first portion 200a. On a plane parallel to one surface of the insulating layer 110, the first portion 200a may extend along one edge of a portion of one surface of the insulating layer 110 exposed from the solder resist layer 200 in the first area 1101. The first portion 200a may extend in the third direction.

The solder resist layer 200 may have a second opening 212 exposing the insulating layer 110 from the solder resist layer 200. The second opening 212 may be opened to expose a portion of one surface of the insulating layer 110 in the first area 1101. The first portion 200a may extend along one edge of the second opening 212. The second opening 212 may be separated from the first opening 211 by the first portion 200a. The second opening 212 may be disposed to be spaced apart from the first opening 211.

The first portion 200a may extend along an edge parallel to the third direction of the connection pad 1211. The first portion 200a may extend in the third direction from the second portion 200b adjacent to one end of the connection pad 1211 in the third direction to the second portion 200b adjacent to the other end of the connection pad 1211 in the third direction. The first portion 200a may be disposed adjacent to the second opening 212 of the solder resist layer 200 exposing the insulating layer 110. The first portion 200a may be disposed adjacent to an inner end portion of the electrode portion 21 in the second direction. The first portion 200a may be disposed on one inner direction surface of the first electronic component 20 of the first connection portion 12.

A plurality of first portions 200a may be provided in the first area 1101. The plurality of first portions 200a may be disposed to face each other in the second direction. The plurality of first portions 200a may be disposed inside the first electronic component 20.

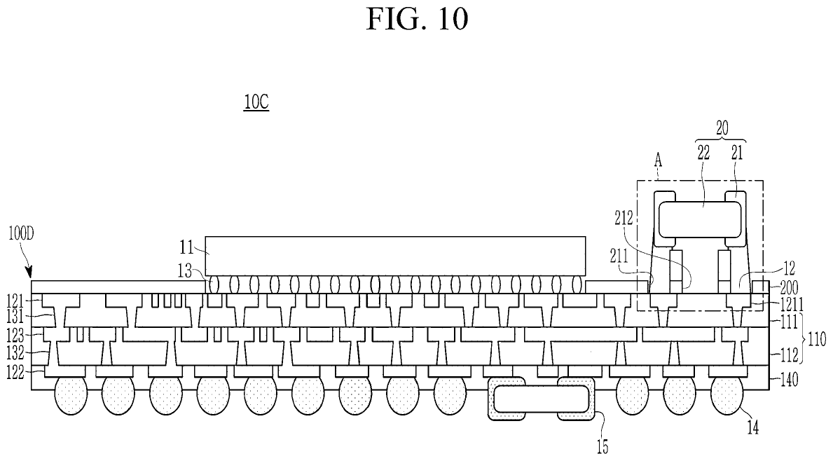

Hereinafter, an electronic component package 10C and a circuit board 100D according to another embodiment will be described with reference to FIG. 10 to FIG. 12.

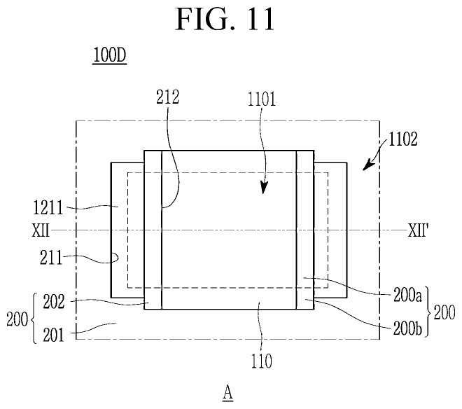

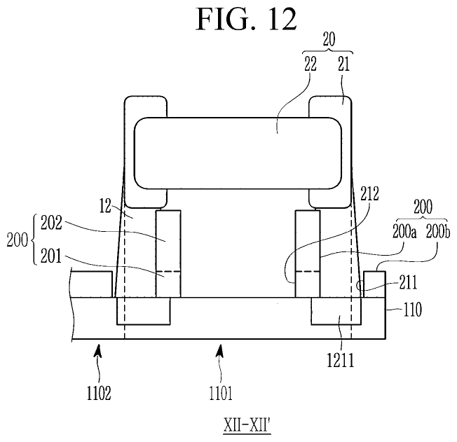

FIG. 10 illustrates a schematic cross-sectional view of an electronic component package according to another embodiment, FIG. 11 illustrates a schematic top plan view of a circuit board according to another embodiment, and FIG. 12 illustrates a cross-sectional view of a portion of an electronic component package according to another embodiment.

FIG. 11 illustrates a top plan view of portion “A” of FIG. 10, excluding electronic components. FIG. 12 illustrates a cross-sectional view of a state in which an electronic component is disposed on a circuit board according to another embodiment taken along line X I-X II′ of FIG. 11.

Referring to FIG. 10 to FIG. 12, in the circuit board 100D according to another embodiment, compared to the circuit board 100C according to another embodiment described with reference to FIG. 7 to FIG. 9, the solder resist layer 200 may include the first and second solder resist layers 201 and 202.

Therefore, in describing the structure of the circuit board 100D according to the present embodiment, only the changed configuration compared to the configuration of the circuit board 100C according to another embodiment described above will be described. The description of the electronic component package 10B according to the above-described embodiment may be applied to the remaining configuration of the electronic component package 10C.

A portion of the solder resist layer 200 may be disposed on the second area 1102. At least a portion of the solder resist layer 200 disposed in the second area 1102 may extend from the second area 1102 to the first area 1101. In other words, the solder resist layer 200 may include a first portion 200a disposed in the first area 1101 and a second portion 200b disposed in the second area 1102.

The first portion 200a of the solder resist layer 200 may be disposed on the first area 1101. The first portion 200a may overlap the first electronic component 20 along the first direction. The first portion 200a may be disposed to overlap a corner portion of the first electronic component 20. The first portion 200a may be disposed to at least partially overlap the connection pad 1211 along the first direction. The first portion 200a may be disposed on the connection pad 1211.

The solder resist layer 200 may be disposed to support the first electronic component 20. The first portion 200a may be disposed to support the first electronic component 20. Along the first direction, the first connection portion 12 may be disposed between the first portion 200a and the first electronic component 20. Along the first direction, there may be a portion in which the first electronic component 20, the first connection portion 12, and the first portion 200a are sequentially disposed. In the height from one surface of the insulating layer 110 in the first direction, the height of the lower surface of the first electronic component 20 may be higher than the height of the upper surface of the first portion 200a. The first portion 200a may be in contact with the first connection portion 12.

The first portion 200a may include a portion that is in direct contact with the first electronic component 20. In the height from one surface of the insulating layer 110 in the first direction, the height of the lower surface of the first electronic component 20 may be the same as the height of the upper surface of the first portion 200a. The first portion 200a may be in contact with the first connection portion 12.

The first portion 200a may be disposed adjacent to one edge of the connection pad 1211. The first portion 200a can be disposed along one edge of the connection pad 1211. The first portion 200a may extend along one edge of the connection pad 1211 disposed in the first area 1101. The first portion 200a may be disposed between the first electronic component 20 and the connection pad 1211 along the first direction. The first portion 200a may be disposed between the electrode portion 21 of the first electronic component 20 and the connection pad 1211 along the first direction.

On a plane parallel to one surface of the insulating layer 110, the first portion 200a may be disposed between the connection pad 1211 and the insulating layer 110 in the second direction. On a plane parallel to one surface of the insulating layer 110, the connection pad 1211 and the insulating layer 110 may be disposed along the second direction with respect to the first portion 200a. On a plane parallel to one surface of the insulating layer 110, the first portion 200a may extend along one edge of a portion of one surface of the insulating layer 110 exposed from the solder resist layer 200 in the first area 1101. The first portion 200a may extend in the third direction.

The solder resist layer 200 may have a second opening 212 exposing the insulating layer 110 from the solder resist layer 200. The second opening 212 may be opened to expose a portion of one surface of the insulating layer 110 in the first area 1101. The second opening 212 may be separated from the first opening 211 by the first portion 200a. The second opening 212 may be disposed to be spaced apart from the first opening 211. The first portion 200a may extend along one edge of the second opening 212.

A plurality of connection pads 1211 may be provided to be spaced apart from each other with the second opening 212 interposed therebetween. The first portion 200a may be disposed between the plurality of connection pads 1211.

The first portion 200a may extend along an edge parallel to the third direction of the connection pad 1211. The first portion 200a may extend in the third direction from the second portion 200b adjacent to one end of the connection pad 1211 in the third direction to the second portion 200b adjacent to the other end of the connection pad 1211 in the third direction. The first portion 200a may be disposed adjacent to the second opening 212 of the solder resist layer 200 exposing the insulating layer 110. The first portion 200a may be disposed adjacent to an inner end portion of the electrode portion 21 in the second direction. The first portion 200a may be disposed on one inner direction surface of the first electronic component 20 of the first connection portion 12.

A plurality of first portions 200a may be provided in the first area 1101. The plurality of first portions 200a may be disposed to face each other in the second direction. The plurality of first portions 200a may be disposed inside the first electronic component 20.

Referring to FIG. 10 to FIG. 12, in a thickness along the first direction, a thickness of the first portion 200a of the solder resist layer 200 may be greater than that of the second portion 200b. Specifically, the solder resist layer 200 may include a protrusion having a thickness greater than that of the remaining portion in the first direction in an area adjacent to the first electronic component 20. In other words, the solder resist layer 200 may include a first solder resist layer 201 disposed on the insulating layer 110 and a second solder resist layer 202 disposed on the first solder resist layer 201. The second solder resist layer 202 may include at least one solder resist patch. The first solder resist layer 201 may have an expanded shape to cover one surface of the insulating layer 110. The first solder resist layer 201 may have a first opening 211 exposing at least a portion of the connection pad 1211 from the first solder resist layer 201.

The second solder resist layer 202 may be disposed to protrude from the first solder resist layer 201 in the first direction. The second solder resist layer may be disposed between the first electronic component 20 and the first solder resist layer 201 along the first direction. The second solder resist layer 202 may be disposed to face the second direction. The second solder resist layer 202 may be disposed at the inner end portion of the electrode portion 21 along the second direction. The second solder resist layer 202 may be disposed between the plurality of electrode portions 21 facing in the second direction.

Along the first direction, the first connection portion 12 may be disposed between the first electronic component 20 and the second solder resist layer 202. Along the first direction, there may be a portion in which the first electronic component 20, the first connection portion 12, the second solder resist layer 202, and the first solder resist layer 201 are sequentially disposed.

In a planar area in a plane parallel to one surface of the insulating layer 110, a planar area of the second solder resist layer 202 may be smaller than that of the first solder resist layer 201. The second solder resist layer 202 may be made of the same material as the first solder resist layer 201, but is not limited thereto, and may be made of a different material.

The first portion 200a may include portions of the first solder resist layer 201 and the second solder resist layer 202. The second portion 200b may include another portion of the first solder resist layer 201.

The first portion 200a may be disposed to support the first electronic component 20. The first portion 200a may be disposed to overlap the first electronic component 20 along the first direction. At least a portion of the first portion 200a may be disposed to overlap the electrode portion 21 in the first direction. At least a portion of the first portion 200a may be disposed to overlap the connection pad 1211 in the first direction. At least a portion of the first portion 200a may be disposed to overlap the connection pad 1211 in the first direction.

The first portion 200a may be disposed to overlap one corner portion of the first electronic component 20 in the first direction. In other words, the first portion 200a may be disposed to overlap one corner portion of the first area 1101 in the first direction.

The first solder resist layer 201 and the second solder resist layer 202 configuring the first portion 200a may be disposed to have the same width in the third direction. However, the present disclosure is not limited thereto, and the first solder resist layer 201 and the second solder resist layer 202 configuring the first portion 200a have different widths in the third direction, so that a stepped portion in the first direction may be disposed at one edge of the first portion 200a in the third direction.

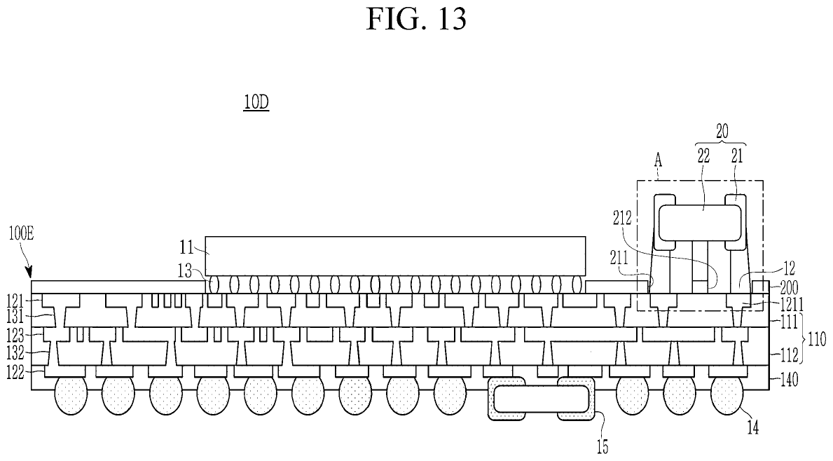

Hereinafter, an electronic component package 10D and a circuit board 100E according to another embodiment will be described with reference to FIG. 13 to FIG. 15.

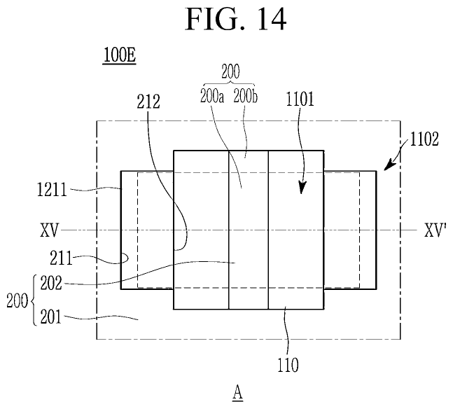

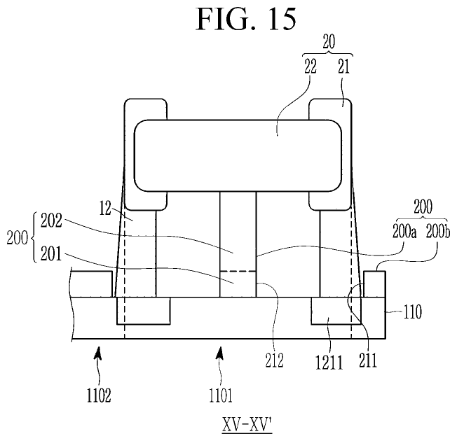

FIG. 13 illustrates a schematic cross-sectional view of an electronic component package according to another embodiment, FIG. 14 illustrates a schematic top plan view of a circuit board according to another embodiment, and FIG. 15 illustrates a cross-sectional view of a portion of an electronic component package according to another embodiment.

FIG. 14 illustrates a top plan view of portion “A” of FIG. 13, excluding electronic components. FIG. 15 illustrates a cross-sectional view of a state in which an electronic component is disposed on a circuit board according to another embodiment taken along line X V-X V′ of FIG. 14.

Referring to FIG. 13 to FIG. 15, the circuit board 100E according to another embodiment may have a different disposition or shape of the first and second solder resist layers 201 and 202 compared to the circuit board 100D according to another embodiment described with reference to FIG. 10 to FIG. 12. Therefore, in describing the structure of the circuit board 100E according to the present embodiment, only the changed configuration compared to the configuration of the circuit board 100D according to another embodiment described above will be described. The description of the electronic component package 10C according to the above-described embodiment may be applied to the remaining configuration of the electronic component package 10D.

A portion of the solder resist layer 200 may be disposed on the second area 1102. At least a portion of the solder resist layer 200 may extend from the second area 1102 to the first area 1101. In other words, the solder resist layer 200 may include a first portion 200a disposed in the first area 1101 and a second portion 200b disposed in the second area 1102.

The first portion 200a of the solder resist layer 200 may be disposed on the first area 1101. The first portion 200a may overlap the first electronic component 20 along the first direction. The first portion 200a may be disposed to overlap a entral portion of the first electronic component 20. The first portion 200a may be disposed to overlap the body 22 along the first direction. The first portion 200a may be disposed to support the first electronic component 20. The first portion 200a may be disposed to overlap the first electronic component 20 along the first direction. The first portion 200a may be disposed to be spaced apart from the connection pad 1211 in the first area 1101. The connection pad 1211 may include a plurality of connection pads, and the first portion 200a may be disposed between the plurality of connection pads.

The solder resist layer 200 may be disposed to support the first electronic component 20. The first portion 200a may be disposed to support the first electronic component 20. The first portion 200a may include a portion that is in direct contact with the first electronic component 20. In the height from one surface of the insulating layer 110 in the first direction, the height of the lower surface of the body 22 of the first electronic component 20 may be the same as the height of the upper surface of the first portion 200a. The first portion 200a may be disposed to be spaced apart from the first connection portion 12.

The first portion 200a may be disposed on the insulating layer 110. The first portion 200a may extend in the third direction. The first portion 200a may be disposed between the body 22 of the first electronic component 20 and the insulating layer 110 along the first direction.

On a plane parallel to one surface of the insulating layer 110, the insulating layer 110 may be disposed at an edge of the first portion 200a facing in the second direction. On a plane parallel to one surface of the insulating layer 110, the insulating layers 110 may be disposed at both sides of the first portion 200a in the second direction. On a plane parallel to one surface of the insulating layer 110, the first portion 200a may extend along one edge of a portion of one surface of the insulating layer 110 exposed from the solder resist layer 200 in the first area 1101.

The solder resist layer 200 may have a second opening 212 exposing the insulating layer 110 from the solder resist layer 200. The second opening 212 may be opened to expose a portion of one surface of the insulating layer 110 in the first area 1101. The second opening 212 may be surrounded by the solder resist layer 200 and one side of the connection pad 1211. The second opening 212 may be integrally connected to the first opening 211. The first portion 200a may extend along one edge of the second opening 212. A plurality of second openings 212 may be provided. The first portion 200a may be disposed between the plurality of second openings 212.

A plurality of connection pads 1211 may be provided to be spaced apart from each other with the second opening 212 interposed therebetween. The first portion 200a may be disposed between the plurality of connection pads 1211.

The first portion 200a may extend in the third direction to connect both areas of the second portion 200b facing in the third direction to each other. The first portion 200a may be disposed adjacent to the second opening 212 of the solder resist layer 200 exposing the insulating layer 110. The first electronic component 20 may include a plurality of electrode portions 21 facing each other in the second direction. The first portion 200a may be disposed between the plurality of electrode portions 21 facing each other in the second direction.

In FIG. 14, the first portion 200a is illustrated in singular, but the present disclosure is not limited thereto, and the first portion 200a may be provided in plural to support the body 22 of the first electronic component 20. The plurality of first portions 200a may be disposed between the plurality of electrode portions 21 facing each other in the second direction.

Referring to FIG. 13 to FIG. 15, in a thickness along the first direction, a thickness of the first portion 200a of the solder resist layer 200 may be greater than that of the second portion 200b. Specifically, the solder resist layer 200 may include a protrusion having a thickness greater than that of the remaining portion in the first direction in an area adjacent to the first electronic component 20. In other words, the solder resist layer 200 may include a first solder resist layer 201 disposed on the insulating layer 110 and a second solder resist layer 202 disposed on the first solder resist layer 201. The second solder resist layer 202 may include at least one solder resist patch. The first solder resist layer 201 may have an expanded shape to cover one surface of the insulating layer 110. The first solder resist layer 201 may have a first opening 211 exposing at least a portion of the connection pad 1211 from the first solder resist layer 201.

The second solder resist layer 202 may be disposed to protrude from the first solder resist layer 201 in the first direction. The second solder resist layer 202 may be disposed between the first electronic component 20 and the first solder resist layer 201 along the first direction. The second solder resist layer 202 may be disposed between the body 22 of the first electronic component 20 and the first solder resist layer 201 along the first direction. The second solder resist layer 202 may be disposed to be in direct contact with the body 22. The second solder resist layer 202 may be disposed between the plurality of electrode portions 21 facing in the second direction.

In a planar area in a plane parallel to one surface of the insulating layer 110, a planar area of the second solder resist layer 202 may be smaller than that of the first solder resist layer 201. The second solder resist layer 202 may be made of the same material as the first solder resist layer 201, but is not limited thereto, and may be made of a different material.

The first portion 200a may include portions of the first solder resist layer 201 and the second solder resist layer 202. The second portion 200b may include another portion of the first solder resist layer 201.

The first solder resist layer 201 and the second solder resist layer 202 configuring the first portion 200a may be disposed to have the same width in the third direction. However, the present disclosure is not limited thereto, and the first solder resist layer 201 and the second solder resist layer 202 configuring the first portion 200a have different widths in the third direction, so that a stepped portion in the first direction may be disposed at one edge of the first portion 200a in the third direction.

According to the circuit board and the electronic component package according to some embodiments described above, by disposing the solder resist layer to support the electronic component, it is possible to secure a sufficient separation distance between the circuit board and the mounted component on the surface of the circuit board, improve cleaning power under the mounted electronic component during the surface mounting process, and prevent defects caused by flux residues. In addition, it is possible to prevent mold void defects under the surface-mounted component during the molding process, and to suppress physical and electrical interference effects between the surface-mounted component and the circuit board.

While this disclosure has been described in connection with what is presently considered to be practical embodiments, it is to be understood that the disclosure is not limited to the disclosed embodiments, but, on the contrary, is intended to cover various modifications and equivalent arrangements included within the spirit and scope of the appended claims.

What is claimed is:

1. A circuit board comprising:
an insulating layer including a first area on one surface on which an electronic component is mounted and a second area adjacent to the first area;
a connection pad disposed in the first area; and
a solder resist layer covering the one surface of the insulating layer and being opened to expose the connection pad,
wherein at least a portion of the solder resist layer extends from the second area to the first area, and
a portion of the insulating layer is exposed from the solder resist layer in the first area.

2. The circuit board of claim 1, wherein
the solder resist layer includes a first portion disposed in the first area and a second portion disposed in the second area, and
the first portion is disposed adjacent to one edge of the connection pad.

3. The circuit board of claim 1, wherein
the solder resist layer includes a first portion disposed in the first area and a second portion disposed in the second area, and
the first portion is disposed to at least partially overlap the connection pad in a first direction perpendicular to the one surface of the insulating layer.

4. The circuit board of claim 1, wherein
the solder resist layer includes:
a first opening opened to expose at least a portion of the connection pad, and
a second opening opened to expose a portion of the insulating layer in the first area, and
the first opening and the second opening are integrally connected.

5. The circuit board of claim 1, wherein
the solder resist layer includes:
a first portion disposed in the first area and a second portion disposed in the second area,
a first opening opened to expose at least a portion of the connection pad, and
a second opening opened to expose a portion of the insulating layer in the first area, and
the first opening and the second opening are separated from each other by the first portion.

6. The circuit board of claim 5, wherein
the first portion extends along one edge of the second opening.

7. A circuit board comprising:
an insulating layer including a first area on one surface on which an electronic component is mounted and a second area adjacent to the first area;
a connection pad disposed in the first area; and
a solder resist layer covering the one surface of the insulating layer and being opened to expose the connection pad,
wherein a thickness, along a first direction perpendicular to the one surface of the insulating layer, of a first portion of the solder resist layer covering the first area is thicker than a thickness, along the first direction perpendicular to the one surface of the insulating layer, of a second portion of the solder resist layer covering the second area.

8. The circuit board of claim 7, wherein
the electronic component includes a body and an electrode portion disposed on the body and connected to the connection pad, and
at least a portion of the first portion is disposed to overlap the connection pad along the first direction.

9. The circuit board of claim 7, wherein
the solder resist layer includes an opening opened to expose a portion of the insulating layer in the first area,
a plurality of the connection pads are provided to be spaced apart from each other with the opening therebetween, and
the first portion is disposed between the plurality of the connection pads.

10. The circuit board of claim 7, wherein
the first portion is disposed to overlap one corner portion of the first area along the first direction.

11. The circuit board of claim 7, wherein
the first portion is disposed to be spaced apart from the connection pad in the first area.

12. The circuit board of claim 7, wherein
the solder resist layer includes:
a first opening opened to expose at least a portion of the connection pad, and
a second opening opened to expose a portion of the insulating layer in the first area.

13. The circuit board of claim 12, wherein
the first opening and the second opening are integrally connected.

14. The circuit board of claim 12, wherein
the first opening and the second opening are separated from each other by the first portion.

15. The circuit board of claim 12, wherein
a plurality of second openings are provided, and
the first portion is disposed between the plurality of second openings.

16. The circuit board of claim 12, wherein
the first portion extends along one edge of the second opening.

17. The circuit board of claim 7, wherein
the solder resist layer includes:
a first solder resist layer disposed on the one surface of the insulating layer, and
a second solder resist layer disposed on the first solder resist layer to protrude from the first solder resist layer in the first direction.

18. The circuit board of claim 17, wherein
in a planar area in a plane parallel to the one surface of the insulating layer, a planar area of the second solder resist layer is smaller than that of the first solder resist layer.

19. An electronic component package comprising:
an insulating layer including a first area and a second area on one surface;
an electronic component mounted in the first area,
a connection pad disposed in the first area; and
a solder resist layer that covers the one surface of the insulating layer, is opened to expose the connection pad, and is disposed to support the electronic component.

20. The electronic component package of claim 19, wherein
the solder resist layer includes a first portion that is disposed to overlap the electronic component in a first direction perpendicular to the one surface of the insulating layer to support the electronic component.

21. The electronic component package of claim 20, wherein
a height of a lower surface of the electronic component from the one surface of the insulating layer along the first direction is equal to a height of an upper surface of the first portion from the one surface of the insulating layer along the first direction or is higher than the height of the upper surface of the first portion from the one surface of the insulating layer along the first direction.

22. The electronic component package of claim 20, wherein
the first portion includes a portion that is in direct contact with the electronic component.

23. The electronic component package of claim 19, further comprising a connection portion arranged to connect the electronic component and the connection pad to each other,
wherein at least a portion of the connection portion is disposed between the electronic component and the solder resist layer along a first direction perpendicular to the one surface of the insulating layer.

24. The electronic component package of claim 19, wherein
the connection pad is embedded in the insulating layer and one surface thereof is exposed from the insulating layer.

25. The electronic component package of claim 19, wherein
the solder resist layer includes:
a first opening opened to expose at least a portion of the connection pad, and
a second opening opened to expose a portion of the insulating layer in the first area.

26. The electronic component package of claim 25, wherein
the first opening and the second opening are integrally connected.

27. The electronic component package of claim 25, wherein
the first opening and the second opening are separated from each other by the first portion.

28. The electronic component package of claim 25, wherein
a plurality of second openings are provided, and
the first portion is disposed between the plurality of second openings.

29. The electronic component package of claim 19, wherein
the electronic component includes a body and an electrode portion disposed on the body and connected to the connection pad, and
the solder resist layer includes:
a first solder resist layer disposed on the one surface of the insulating layer, and
a second solder resist layer disposed on the first solder resist layer to protrude from the first solder resist layer in a first direction perpendicular to the one surface of the insulating layer.

30. The electronic component package of claim 29, wherein
the second solder resist layer is disposed at both end portions facing each other of the electrode portion.

31. The electronic component package of claim 29, wherein
a plurality of electrode portions are provided so as to be disposed to face each other in a second direction perpendicular to the first direction, and
the second solder resist layer is disposed at an inner end portion of the electrode portion in the second direction.

32. The electronic component package of claim 29, wherein
a plurality of electrode portions are provided so as to be disposed to face each other in a second direction perpendicular to the first direction, and
the second solder resist layer is disposed between the plurality of electrode portions.

33. The electronic component package of claim 29, wherein
the second solder resist layer is disposed between the body of the electronic component and the first solder resist layer in the first direction.

34. A circuit board comprising:
an insulating layer;
a connection pad at least partially embedded in the insulating layer and having one surface exposed from the insulating layer;
a solder resist layer disposed on the insulating layer; and
a first electronic component disposed on the insulating layer and connected to the connection pad through a connection portion disposed between the connection pad and the first electronic component,
wherein a portion of the solder resist layer overlapping the first electronic component in a first direction perpendicular to the one surface includes one opening to expose a portion of the insulating layer.

35. The circuit board of claim 34, wherein
the connection portion is disposed in the one opening of the solder resist layer.

36. The circuit board of claim 34, wherein
the connection portion is disposed in another opening of the solder resist layer spaced apart from the one opening of the solder resist layer.

37. The circuit board of claim 34, wherein
a thickness of the portion of the solder resist layer overlapping the first electronic component in the first direction is greater than a thickness of another portion of the solder resist layer disposed on a region outside the first electronic component viewed in the first direction.

38. The circuit board of claim 34, wherein
the solder resist layer includes one portion disposed on one side of the connection portion having a thickness greater than another portion disposed on another side of the connection portion.

39. The circuit board of claim 34, wherein
the solder resist layer includes another opening exposing a plurality of other pads partially embedded in the insulating layer, and
the circuit board further comprises a second electronic component disposed on the insulating layer and connected to the plurality of other connection pads through other connection portions disposed in the another opening of the solder resist layer.

40. The circuit board of claim 39, wherein
a portion of the solder resist layer extending in a region between the first electronic component and the second electronic component has a thickness less than the portion of the solder resist layer overlapping the first electronic component in the first direction.

41. A circuit board comprising:
an insulating layer;
a connection pad at least partially embedded in the insulating layer and having one surface exposed from the insulating layer;
a solder resist layer disposed on the insulating layer; and
a first electronic component disposed on the insulating layer and connected to the connection pad through a connection portion disposed between the connection pad and the first electronic component,
wherein the solder resist layer includes one opening to expose a portion of the insulating layer which overlaps the first electronic component in a first direction perpendicular to the one surface, and
in the first direction perpendicular to the one surface, a lower surface of the first electronic component is at a level the same as or above an upper surface of the solder resist layer.

42. The circuit board of claim 41, wherein
the connection portion is disposed in the one opening of the solder resist layer.

43. The circuit board of claim 41, wherein
the connection portion is disposed in another opening of the solder resist layer spaced apart from the one opening of the solder resist layer.

44. The circuit board of claim 41, wherein
a thickness of a portion of the solder resist layer overlapping the first electronic component in the first direction is greater than a thickness of another portion of the solder resist layer disposed on a region outside the first electronic component viewed in the first direction.

45. The circuit board of claim 41, wherein
the solder resist layer includes one portion disposed on one side of the connection portion having a thickness greater than another portion disposed on another side of the connection portion.

46. The circuit board of claim 41, wherein
the solder resist layer includes another opening exposing a plurality of other pads partially embedded in the insulating layer, and
the circuit board further comprises a second electronic component disposed on the insulating layer and connected to the plurality of other connection pads through other connection portions disposed in the another opening of the solder resist layer.

47. The circuit board of claim 41, wherein
the connection portion is in contact with the solder resist layer.
